(19) United States
(12) Patent Application Publication
(10) Pub. No.: US 2011/0097904 A1
(43) Pub. Date: Apr. 28, 2011

(54) METHOD FOR REPAIRING LOW-K DIELECTRIC DAMAGE

(75) Inventors: Stephen M. Sirard, San Jose, CA (US); Kenji Takeshita, Sunnyvale, CA (US); Andrew D. Bailey, III, Pleasanton, CA (US)

(73) Assignee: LAM RESEARCH CORPORATION, Fremont, CA (US)

(21) Appl. No.: 12/604,224

(22) Filed: Oct. 22, 2009

(51) Int. Cl. H01L 21/3065

(52) U.S. Cl. 438/719; 438/694; 156/345.26; 257/E21.218

(57) ABSTRACT

A method for repairing damage to a silicon based low-k dielectric layer with organic compounds, where damage replaces a methyl attached to silicon with a hydroxyl attached to silicon is provided. A repair gas comprising CH₄ gas is provided. The repair gas is formed into a plasma, while maintaining a pressure below 50 mTorr. Hydroxyl attached to silicon is replaced with methyl from the plasma formed by the repair gas.

### BACKGROUND OF THE INVENTION

1. Field of the Invention

The invention relates to a method of obtaining a structure on a semiconductor wafer by etching through a low-k silicon based organic dielectric layer.

2. Description of the Related Art

In semiconductor plasma etching applications, a plasma etcher is usually used to transfer an organic mask pattern, such as a photoresist mask pattern, into a circuit and line pattern of a desired thin film and/or filmstack (conductors or dielectric insulators) on a Si wafer. This is achieved by etching away the films (and filmstacks) underneath the photoresist materials in the opened areas of the mask pattern. This etching reaction is initiated by the chemically active species and electrically charged particles (ions) generated by exciting an electric discharge in a reactant mixture contained in a vacuum enclosure, also referred to as a reactor chamber. Additionally, the ions are also accelerated towards the wafer materials through an electric field created between the gas mixture and the wafer materials, generating a directional removal of the etching materials along the direction of the ion trajectory in a manner referred to as anisotropic etching. At the finish of the etching sequence, the masking materials are removed by stripping it away, leaving in its place a replica of the lateral pattern of the original intended mask patterns.

### SUMMARY OF THE INVENTION

To achieve the foregoing and in accordance with the purpose of the present invention, a method for repairing damage to a silicon based low-k dielectric layer with organic compounds, where damage replaces a methyl attached to silicon with a hydroxyl attached to silicon is provided. A repair gas comprising CH₄ gas is provided. The repair gas is formed into a plasma, while maintaining a pressure below 50 mTorr. Hydroxyl attached to silicon is replaced with methyl from the plasma formed by the repair gas.

In another manifestation of the invention, a method for forming features in a silicon based low-k dielectric layer with organic compounds over a wafer is provided. The wafer is placed in a plasma etch chamber. The wafer is chucked to a wafer support. Features are etched into the silicon based low-k dielectric layer with organic compounds. Damage to a silicon based low-k dielectric layer with organic compounds is repaired by providing a repair gas comprising CH₄ gas and forming the repair gas into a plasma, while maintaining a pressure below 50 mTorr. Hydroxyl attached to silicon is replaced with methyl from the plasma formed by the repair gas. The wafer is only dechucked after the repairing is completed.

In another manifestation of the invention, an apparatus for forming features in a silicon based low-k dielectric layer with organic compounds over a wafer and under a mask is provided. A plasma processing chamber comprising a chamber wall forming a plasma processing chamber enclosure, a substrate support for supporting a wafer within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure is provided. A gas source is in fluid connection with the gas inlet and comprises a CH₄ containing gas source, an etching gas source, and a stripping gas source. A controller is controllably connected to the gas source and the at least one electrode and comprises at least one processor and computer readable media. The computer readable media comprises computer readable code for chucking the wafer to the substrate support; computer readable media for etching features into the silicon based low-k dielectric layer with organic compounds, computer readable code for stripping the mask, computer readable code repairing damage to a silicon based low-k dielectric layer with organic compounds, comprising computer readable code for providing a repair gas comprising CH₄ gas from the CH₄ containing gas source and computer readable code for forming the repair gas into a plasma, while maintaining a pressure below 50 mTorr, and computer readable code for replacing hydroxyl attached to silicon with methyl from the plasma formed by the repair gas, and computer readable code for dechucking the wafer, only after repairing damage.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIGS. 2A-B are schematic views of the formation of a feature using the inventive process.

FIG. 3 is a schematic view of a system that may be used in practicing the invention.

FIG. 4 is a schematic view of a plasma processing chamber that may be used in an embodiment of the invention.

FIGS. 5A-B are schematic views of a computer system that may be used in practicing the invention.

FIG. 6 is a graph of the Si—O—Si to Si—C ratio for pristine ULK, damaged ULK and repaired ULK.

FIG. 7 shows the water contact angle for a pristine ULK, damaged ULK and repaired ULK.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As dimensions of integrated circuit devices continue to decrease, propagation delay must be decreased, which may be done by lowering the capacitance of surrounding dielectric material. In the specification and claims, a low-k material is defined as having a dielectric constant k<3.0. Such low-k dielectric materials may be silicon based, such as silicon oxide, with organic compounds, to lower the dielectric constant, such as organosilicate glass (OSG). For silicon based low-k dielectric materials, such material may be formed to be an ultra low-k (k<2.8) by forming nanopores in the low-k dielectric material, which is referred to as nanoporous ultra low-k dielectric material.

In semiconductor via first trench last (VFTL) dual damascene (DD) processing, silicon oxide based low dielectric constant (low-k) materials with added organic components to provide a lower dielectric constant are exposed to various reactants during etch and resist strip process. The exposed low-k dielectric materials are often damaged by etch/strip plasmas and chemicals. In general, low-k damage includes changes in material composition (e.g., carbon depletion), morphology (density or porosity), and/or surface property (e.g., hydrophobic to hydrophilic). The damaged layer no longer possesses the intended dielectric properties, and can lead to device yield loss and/or reliability failures. Therefore, reducing damage during low-k dielectric etch/strip has become one of the most critical challenges in semiconductor processing. Unlike the pristine (undamaged) low-k materials, the damaged layer can be readily removed by dilute HF solution. It is a common practice to quantify low-k material damage after etch and strip by measuring the material loss after dipping the sample in dilute HF solution. For nanoporous ultra low-k dielectric material, such damage may be increased because the pores provide an increased surface area over which the damage may occur and they may lead to enhanced diffusion of damaging radicals within the dielectric film.

Efforts have been made to reduce damage during low-k dielectric etch and strip processes. The prior art methods of the optimization of etch and strip processes by optimizing process chemistry, hardware configuration, and/or plasma sources (e.g. RF vs. microwave) etc. have resulted in only limited success. As the dielectric constant (k value) continues to reduce, and the material becomes more porous, and the critical dimension becomes smaller, damage becomes a more severe issue in the most advanced integrated circuit processing.

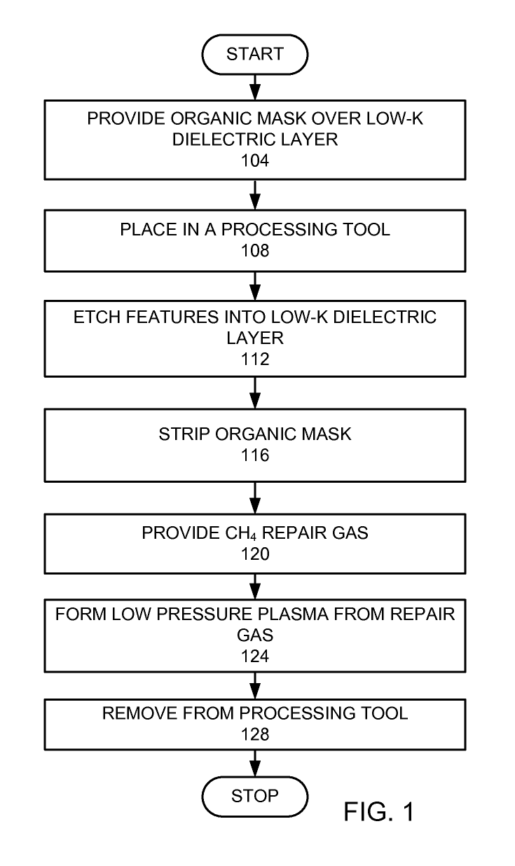

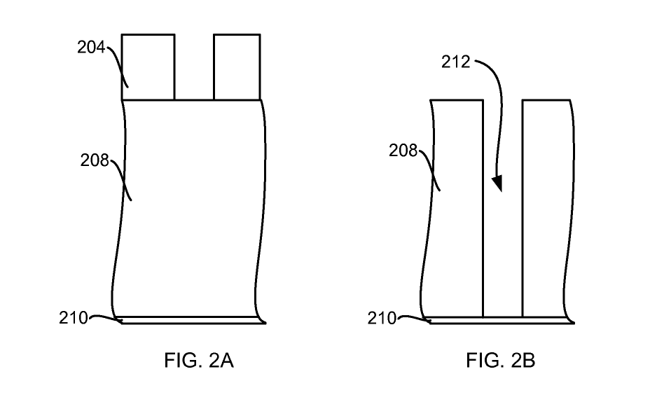

FIG. 1 is a high level flow chart of an embodiment of the invention. In this embodiment, a patterned organic mask is formed over a low-k dielectric layer (step 104). FIG. 2A is a schematic cross-sectional view of a substrate 210, over which a low-k dielectric layer 208 is disposed, over which a patterned organic mask 204 has been form. One or more intermediate layers may be disposed between the substrate (wafer) 210 and the low-k dielectric layer 208. One or more intermediate layers, such as an antireflective coating, may be disposed between the low-k dielectric layer 208 and the patterned organic mask 204.

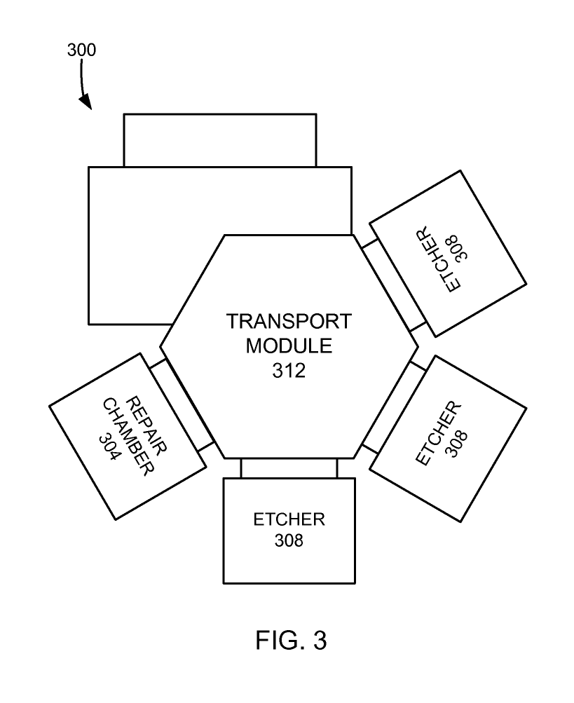

The substrate 210 is placed in a processing tool (step 108). FIG. 3 is a schematic top view of a processing tool 300 that may be used in the preferred embodiment of the invention. In this embodiment, the processing tool 300 comprises a repair chamber 304, a plurality of plasma processing chambers, such as etchers 308, and a transport module 312. The transport module 312 is placed between the repair chamber 304 and etchers 308 to allow movement of a wafer into and out of the repair chamber 304 and plurality of etchers 308, while maintaining a vacuum.

In this embodiment, the substrate 210 is placed in the transport module 312 of the processing tool 300, where a vacuum is created. The transport module 312 moves the substrate 210 into an etcher 308. In the etcher 308, an etch is performed to form features into the low-k dielectric layer (step 112). In this embodiment, the organic mask is then stripped (step 116). FIG. 2B is a schematic cross-sectional view of a substrate 210 and low-k dielectric layer 208 after features 212 have been etched into the low-k dielectric layer 208 and the organic mask has been stripped. In this embodiment, the stripping is performed in the etcher 308. In other embodiments, a strip tool may be connected to the transport module 312, where the transport module 312 moves the substrate 210 from the etcher 208 to a strip tool, without breaking the vacuum.

The transport module 312 then moves the substrate 210 to the repair chamber 304. Preferably, a single plasma processing chamber with a single electrostatic chuck holds the substrate 210 during the etching, stripping and repairing, which are done in the single plasma processing chamber.

In the repair chamber 304, a CH₄ containing repair gas is provided (step 120). Preferably, the CH₄ containing gas is at least 5% CH₄ by molar flow rate with the balance being an inert gas such as N₂ or Ar. More preferably, the repair gas is at least 50% CH₄ by molar flow. Most preferably, the repair gas consists essentially of CH₄. The CH₄ containing repair gas is formed into a low pressure plasma (step 124). Preferably, the low pressure plasma is maintained at a pressure of less than 50 mTorr. Preferably the plasma is formed with a bias voltage of between 0 V and −100V. Preferably, the plasma is maintained sufficiently long enough to provide a repair layer with a thickness of less than 5 Å. The substrate may then be removed from the processing tool 300 (step 128).

### Example

A more specific example of an embodiment of the invention provides a substrate 210 where the low-k dielectric layer 208 is a nanoporous organosilicate glass. The organic mask 204 is a multi-layer photoresist mask comprising 193 nm photoresist, an organic antireflective coating, and an organic planarization layer (step 104).

The substrate 210 is placed in a the processing tool 300 (step 108). In this example, the substrate 210 is placed in the transport module 312 of the processing tool 300. The transport module 312 moves the substrate 210 to an etcher 308. In this example features 212 (FIG. 2B) are etched into the low-k dielectric layer (step 112) and the organic mask is stripped (step 116) in the etcher 308. Conventional organosilicate glass etching and photoresist stripping processes may be used.

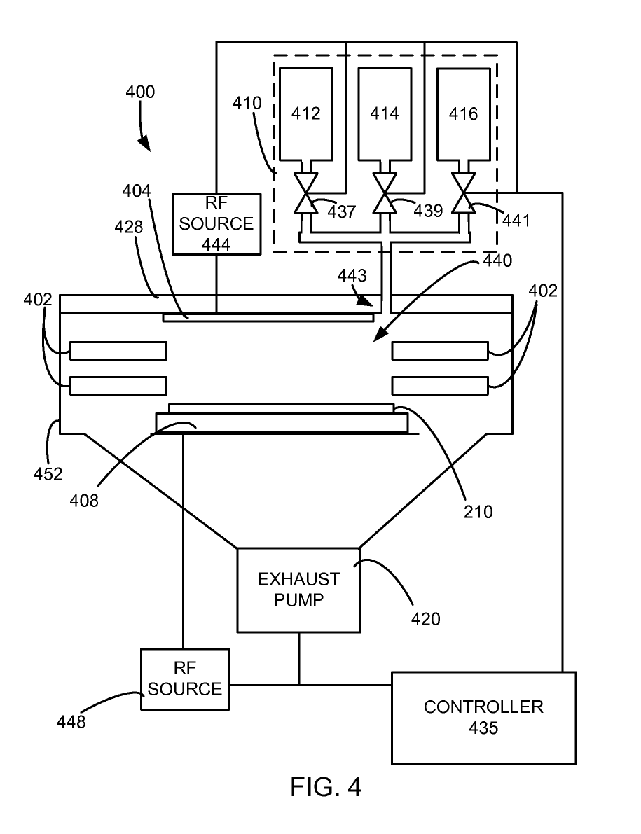

In this example, the transport module 312 moves the substrate 210 to the repair chamber 304. FIG. 4 is a schematic view of a plasma processing chamber 400 that may be used in the preferred embodiment of the invention for treating the repair layer. In this embodiment, the plasma processing chamber 400 comprises confinement rings 402, an upper electrode 404, a lower electrode 408, a gas source 410, and an exhaust pump 420. The gas source 410 comprises a CH₄ gas source 412. Other gas sources 414, 416 may be provided to either provide other repair gas components or to provide gases to perform other tasks, such as stripping the photoresist. Within plasma processing chamber 400, the substrate 210 is positioned upon the lower electrode 408. The lower electrode 408 incorporates a suitable substrate chucking mechanism (e.g., electrostatic, mechanical clamping, or the like) for holding the substrate 210. The reactor top 428 incorporates the upper electrode 404 disposed immediately opposite the lower electrode 408. The upper electrode 404, lower electrode 408, and confinement rings 402 define the confined plasma volume 440. Gas is supplied to the confined plasma volume by gas source 410 through a gas inlet 443 and is exhausted from the confined plasma volume through the confinement rings 402 and an exhaust port by the exhaust pump 420. The exhaust pump 420 forms a gas outlet for the plasma processing chamber. A first RF source 444 is electrically connected to the upper electrode 404. A second RF source 448 is electrically connected to the lower electrode 408. Chamber walls 452 define a plasma enclosure in which the confinement rings 402, the upper electrode 404, and the lower electrode 408 are disposed. Both the first RF source 444 and the second RF source 448 may comprise a 60 MHz power source, a 27 MHz power source, and a 2 MHz power source. Different combinations of connecting RF power to the electrode are possible. A 2300® Exelan® Flex EL dielectric etch system made by Lam Research Corporation™ of Fremont, Calif. may be used in a preferred embodiment of the invention. A controller 435 is controllably connected to the first RF source 444, the second RF source 448, the exhaust pump 420, a first control valve 437 connected to the CH₄ gas source 412, a second control valve 439 and a third control valve 441 connected to the gas sources 414, 416. The gas inlet 443 provides gas from the gas sources 412, 414, 416 into the plasma processing enclosure. A showerhead may be connected to the gas inlet 443. The gas inlet 443 may be a single inlet for each gas source or a different inlet for each gas source or a plurality of inlets for each gas source or other possible combinations.

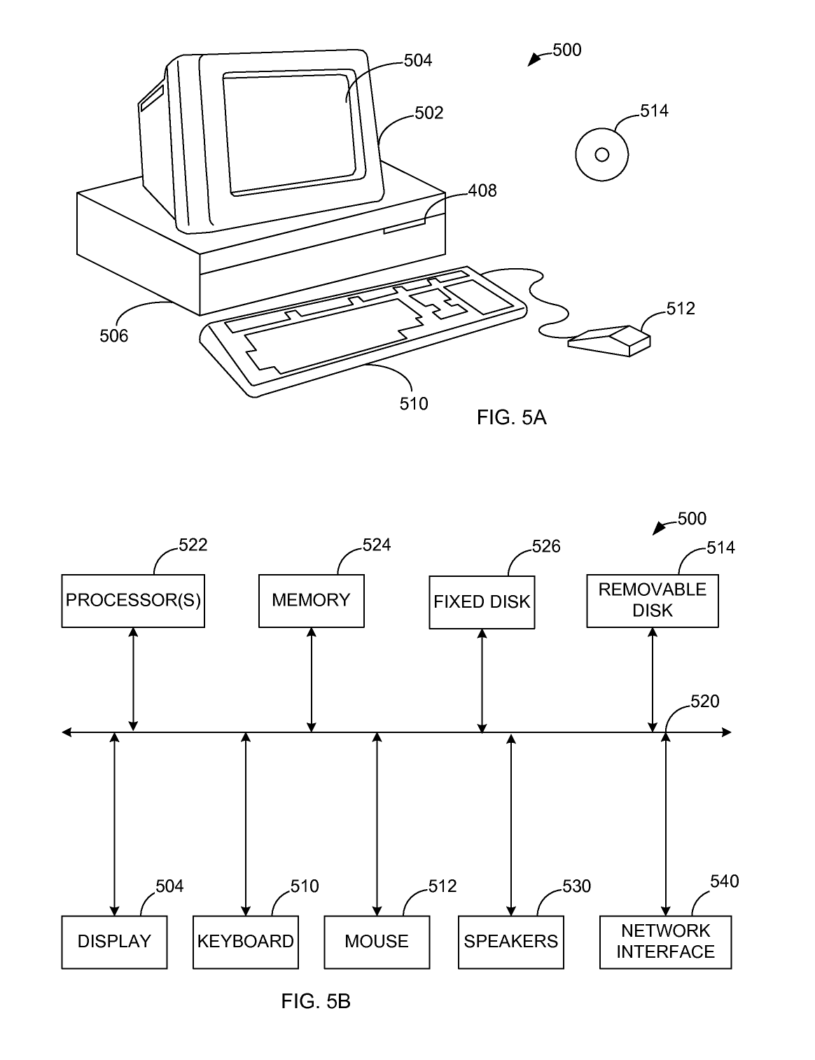

FIGS. 5A and 5B illustrate a computer system 500, which is suitable for using as a controller for the processing tool. Such a controller may be used to transport the substrates between different process chambers and to control the processes in the process chamber.

FIG. 5A shows one possible physical form of a computer system that may be used for the controller 435. Of course, the computer system may have many physical forms ranging from an integrated circuit, a printed circuit board, and a small handheld device up to a huge super computer. Computer system 500 includes a monitor 502, a display 504, a housing 506, a disk drive 508, a keyboard 510, and a mouse 512. Disk 514 is a computer-readable medium used to transfer data to and from computer system 500.

FIG. 5B is an example of a block diagram for computer system 500. Attached to system bus 520 is a wide variety of subsystems. Processor(s) 522 (also referred to as central processing units, or CPUs) are coupled to storage devices, including memory 524. Memory 524 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable type of the computer-readable media described below. A fixed disk 526 is also coupled bi-directionally to CPU 522; it provides additional data storage capacity and may also include any of the computer-readable media described below. Fixed disk 526 may be used to store programs, data, and the like and is typically a secondary storage medium (such as a hard disk) that is slower than primary storage. It will be appreciated that the information retained within fixed disk 526 may, in appropriate cases, be incorporated in standard fashion as virtual memory in memory 524. Removable disk 514 may take the form of any of the computer-readable media described below.

CPU 522 may be also coupled to a variety of input/output devices, such as display 504, keyboard 510, mouse 512, and speakers 530. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 522 optionally may be coupled to another computer or telecommunications network using network interface 540. With such a network interface, it is contemplated that the CPU might receive information from the network, or might output information to the network in the course of performing the above-described method steps. Furthermore, method embodiments of the present invention may execute solely upon CPU 522 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of tangible computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

In this example, a plasma is generated by supplying RF power of 50 watts at 60 MHz to a gas flow of 100 sccm of CH₄ at a pressure of 50 mTorr for 15 seconds. The wafer temperature is maintained at 20 C. Preferably, the RF power frequency of at least 27 MHz has a power between 5 to 50 watts.

The transport module 312 moves the substrate 210 from the repair chamber 304 out of the processing tool 300 (step 128).

In another preferred embodiment, a single plasma processing chamber, such as the processing chamber 400 may be used for etching, stripping, and repair, wherein the substrate 210 is electrostatically bound to the lower electrode 408 during the etching, stripping, and repair.

In an embodiment of the invention, a plasma tuning may be provided after the repair process and before the substrate is removed from the processing tool. Such tuning is described in U.S. Pat. Application No. ______, entitled METHOD FOR TUNABLY REPAIRING LOW-K DIELECTRIC DAMAGE, by Stephen Sirard et al., filed on the same date as the present application, with Attorney Docket Number LAM1P291/P1972, and incorporated by reference for all purposes.

An advantage of the inventive process is that the inventive process provides a cleaner deposition. Other polymer ingredients are believed to provide too much polymerization. It is also believed that the low bias reduces faceting.

### Experimental Results

In an experiment comparing damage without the inventive process with damage using the inventive process using an above recipe on a 55 nm half pitch trench structures, the following results were found: The etched features without the inventive CH₄ recovery process was found to have 7 nm of physical sidewall damage after a 45 second 100:1 HF dip, where etched features with the inventive CH₄ recovery process was found to have less than 3 nm of physical sidewall damage after a 45 second 100:1 HF dip. Normalized line-to-line capacitance for features without the inventive CH₄ recover was found to be 1, wherein the normalized line-to-line capacitance for features with the inventive CH₄ recover was found to be 0.9. Therefore, it can be seen that the CH₄ recovery reduces the physical sidewall damage.

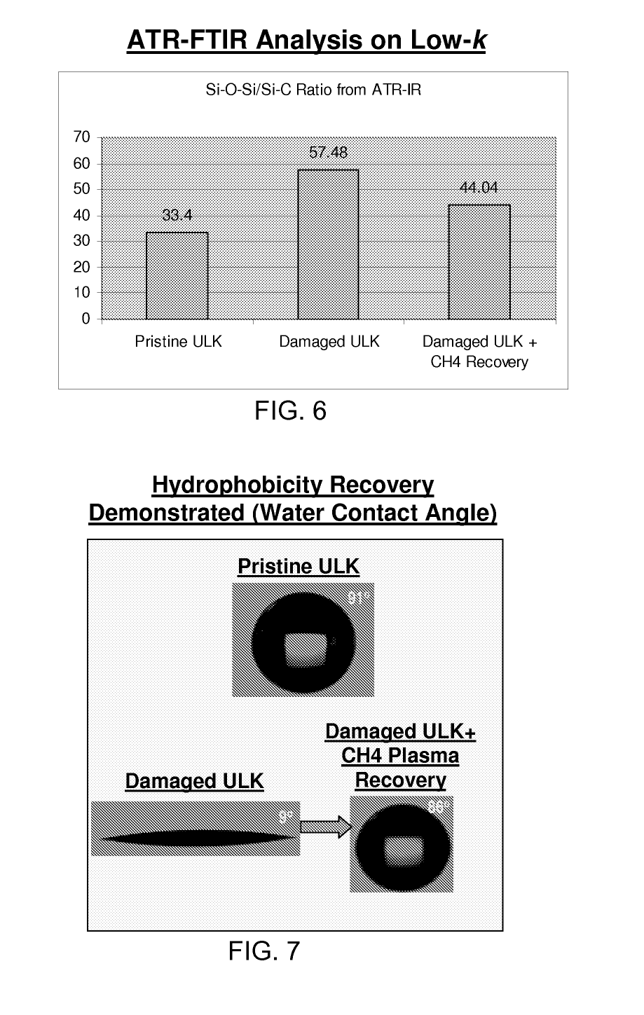

In another experiment, analysis was performed on an ultra low-k dielectric layer (ULK) before damage was done on the ULK, after damage was done on the ULK, and after the inventive repair was performed on the damaged ULK. FIG. 6 shows the Si—O—Si to Si—C ratio from an ATR-IR that measures the pristine ULK, damaged ULK and repaired ULK. For a pristine ULK the Si—O to Si—C ratio is 33.4. The resulting damaged ULK has a Si—O to Si—C ratio of 57.48, indicating depleted carbon in the damaged ULK. The CH₄ recovery method applied to a damaged ULK provides a resulting ULK with a Si—O to Si—C ratio of 44.04, which shows that the CH₄ recovery method recovers most of the lost carbon. FIG. 7 shows the water contact angle for a pristine ULK, damaged ULK and repaired ULK. As shown in FIG. 7, the pristine ULK has a water contact angle of 91°. The damaged ULK has a hydrophilic water contact angle of 9°, which is a significant reduction from the pristine ULK. The repaired ULK has a hydrophobic water contact angle of 86°, which shows that the recovery is almost complete.

While this invention has been described in terms of several preferred embodiments, there are alterations, permutations, and substitute equivalents, which fall within the scope of this invention. It should also be noted that there are many alternative ways of implementing the methods and apparatuses of the present invention. It is therefore intended that the following appended claims be interpreted as including all such alterations, permutations, and substitute equivalents as fall within the true spirit and scope of the present invention.

What is claimed is:

1. A method for repairing damage to a silicon based low-k dielectric layer with organic compounds, where damage replaces a methyl attached to silicon with a hydroxyl attached to silicon, comprising:
providing a repair gas comprising CH₄ gas; and
forming the repair gas into a plasma, while maintaining a pressure below 50 mTorr;
replacing hydroxyl attached to silicon with methyl from the plasma formed by the repair gas.

2. The method, as recited in claims 1, wherein a flow of CH₄ is at least 5% of a molar flow of the repair gas.

3. The method, as recited in claim 2, wherein the forming the plasma uses a bias voltage 0 V to −100 V.

4. The method, as recited in 3, further comprising providing an RF power with a frequency of at least 27 MHz and a power between 5 to 50 watts.

5. The method, as recited in claim 4, wherein the plasma is maintained for a time sufficient to provide a bonded hydrocarbon layer with a thickness of less than 5 Å.

6. The method, as recited in claim 5, further comprising:
forming a photoresist mask over the silicon based low-k dielectric layer;
etching the silicon based low-k dielectric layer through the photoresist mask; and
stripping the photoresist mask, before providing the repair gas.

7. The method, as recited in claim 6, wherein the silicon based low-k dielectric layer is a nanoporous ultra low-k dielectric layer.

8. The method, as recited in claim 7, further comprising maintaining the substrate temperature below 60° C.

9. The method, as recited in claims 8, wherein a flow of CH₄ is at least 50% of a molar flow of the repair gas.

10. The method, as recited in claim 8, wherein the repair gas consists essentially of CH₄.

11. The method, as recited in claim 1, wherein the silicon based low-k dielectric layer is a nanoporous ultra low-k dielectric layer.

12. The method, as recited in claim 1, wherein the repair gas consists essentially of CH₄.

13. A method for forming features in a silicon based low-k dielectric layer with organic compounds over a wafer, comprising:
placing the wafer in a plasma etch chamber;
chucking the wafer to a substrate support;
etching features into the silicon based low-k dielectric layer with organic compounds;
repairing damage to a silicon based low-k dielectric layer with organic compounds, comprising:
providing a repair gas comprising CH₄ gas; and
forming the repair gas into a plasma, while maintaining a pressure below 50 mTorr; and
replacing hydroxyl attached to silicon with methyl from the plasma formed by the repair gas; and
dechucking the wafer, wherein the wafer is dechucked only after repairing the damage.

14. The method, as recited in claim 13, wherein a mask is over the silicon based low-k dielectric layer with organic compounds, and further comprising stripping the mask.

15. The method, as recited in claim 14, wherein the etching, repairing, and stripping are performed in the plasma etch chamber.

16. The method, as recited in claims 14, wherein a flow of CH₄ is at least 5% of a molar flow of the repair gas.

17. The method, as recited in claim 16, wherein the forming the plasma uses a bias voltage between 0 V to −100 V, further comprising providing an RF power with a frequency of at least 27 MHz and a power between 5 to 50 watts and wherein the plasma is maintained for a time sufficient to provide a bonded hydrocarbon layer with a thickness of less than 5 Å.

18. The method, as recited in claim 15, wherein the repair gas consists essentially of CH₄.

19. The method, as recited in claim 13, wherein the repair gas consists essentially of CH₄.

20. An apparatus for forming features in a silicon based low-k dielectric layer with organic compounds over a wafer and under a mask, comprising:
a plasma processing chamber, comprising:
a chamber wall forming a plasma processing chamber enclosure;
a substrate support for supporting a wafer within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising:
a CH₄ containing gas source;
an etching gas source; and
a stripping gas source; and
a controller controllably connected to the gas source and the at least one electrode, comprising:
at least one processor; and
computer readable media, comprising:
computer readable code for chucking the wafer to the wafer support;
computer readable code for etching features into the silicon based low-k dielectric layer with organic compounds;
computer readable code for stripping the mask;
computer readable code repairing damage to a silicon based low-k dielectric layer with organic compounds, comprising:
computer readable code for providing a repair gas comprising CH₄ gas from the CH₄ containing gas source; and
computer readable code for forming the repair gas into a plasma, while maintaining a pressure below 50 mTorr; and
computer readable code for replacing hydroxyl attached to silicon with methyl from the plasma formed by the repair gas; and
computer readable code for dechucking the wafer from the wafer support.
